(19) United States
(12) Patent Application Publication
(10) Pub. No.: US 2008/0315406 A1
(43) Pub. Date: Dec. 25, 2008

(54) INTEGRATED CIRCUIT PACKAGE SYSTEM WITH CAVITY SUBSTRATE

(76) Inventors: Jae Han Chung, Ichon-si (KR); HeeJo Chi, Daejeon-si (KR); HanGil Shin, Ichon-si (KR); SunMi Kim, Gyangju-si (KR)

Correspondence Address: LAW OFFICES OF MIKIO ISHIMARU, 333 W. EL CAMINO REAL, SUITE 330, SUNNYVALE, CA, 94087, US

(21) Appl. No.: 11/767,820

(22) Filed: Jun. 25, 2007

(51) Int. Cl. H01L 23/02; H01L 21/60

(52) U.S. Cl. 257/723; 438/109; 257/E23.18; 257/E21.506

(57) ABSTRACT

An integrated circuit package system includes a base substrate having a base substrate cavity, attaching a junction integrated circuit package over the base substrate with a portion of the junction integrated circuit package in the base substrate cavity, and attaching a base integrated circuit over the junction integrated circuit package and the base substrate.

### TECHNICAL FIELD

The present invention relates generally to integrated circuit package systems, and more particularly to a system for integrated circuit packages with cavity substrate.

### BACKGROUND ART

The demands for smaller, higher performance semiconductor devices have motivated the development of new techniques for producing smaller and less expensive semiconductor devices. One of these technologies involves packaging the integrated circuit chip in as small a form factor as possible and manufacturing the integrated circuit chip as efficiently as possible.

Usually, many individual devices are constructed on the same wafer. When the devices are separated into individual rectangular units, each takes the form of an integrated circuit chip. In order to interface a chip with other circuitry, it is common to mount it with lead fingers and individually connect pad on the chip to the lead fingers using extremely fine wires. The assemblies are then packaged by individually encapsulating them in molded plastic or ceramic bodies.

Virtually all electronic products benefit from increasing features (including functions and performance) in integrated circuit chips all while being designed into ever smaller physical space. These demands are often very visible with the many consumer electronic products including but not limited to personal portable devices, such as cellular phones, digital cameras, and music players.

Integrated circuit packaging technology has shown an increase in the number of chips mounted on a single circuit board or substrate that parallels the reduction in the number of components needed for a circuit. This results in packaging designs that are more compact, in the physical size and shape of a device, and in a significant increase in overall integrated circuit density. However, integrated circuit density continues to be limited by the area available for mounting chips on a substrate.

To condense the packaging of individual devices, packages have been developed in which more than one device can be packaged at one time at each package site. Each package site is a structure that provides mechanical support for the individual integrated circuit devices. It also provides one or more layers of interconnect lines that enable the devices to be connected electrically to surrounding circuitry.

In some cases, multi-chip devices can be fabricated faster and more cheaply than a corresponding single integrated circuit chip, that incorporates all the same functions. Some multi-chip modules have been found to increase circuit density and miniaturization, improve signal propagation speed, reduce overall device size, improve performance, and lower costs.

However, such multi-chip modules can be bulky. Package density is determined by the area required to mount a chip or module on a circuit board. One method for reducing the board size of multi-chip modules and thereby increase their effective density is to stack the chips vertically within the module or package. Such designs are improvements over prior packages that combined several chips and associated passive components side by side in a single, horizontal layer.

However, multi-chip modules, whether vertically or horizontally arranged, can also present problems because they usually must be assembled before the chips and chip connections can be tested. That is, because the electrical bond pads on a chip are so small, it is difficult to test chips before assembly into a package.

When chips are mounted and connected individually, the chip and connections can be tested, and a known-good-unit free of defects is then assembled into larger circuits. A fabrication process that uses a known-good-unit is therefore more reliable and less prone to assembly defects introduced due to bad chips. With conventional multi-chip modules, the chip cannot be individually identified as a known-good-unit before final assembly.

Despite the advantages of recent developments in semiconductor fabrication and packaging techniques, there is a continuing need for improving compatibility of components, electrical failure rates, and final product size.

Thus, a need still remains for an integrated circuit package system to provide a lower profile, increase the number of devices in a package system, and reduce delamination, adhesive, and adhesion failures. In view of the increasing demand for improved density of integrated circuits and particularly portable electronic products, it is increasingly critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a base substrate having a base substrate cavity, attaching a junction integrated circuit package over the base substrate with a portion of the junction integrated circuit package in the base substrate cavity, and attaching a base integrated circuit over the junction integrated circuit package and the base substrate.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit package system taken along line 1-1 of FIG. 2 in an embodiment of the present invention;

FIG. 2 is a top plan view of the integrated circuit package system;

FIG. 3 is a cross-sectional view of an integrated circuit package system in a first embodiment of the present invention;

FIG. 4 is a cross-sectional view of an integrated circuit package system in a second embodiment of the present invention;

FIG. 5 is a cross-sectional view of an integrated circuit package system in a third embodiment of the present invention;

FIG. 6 is a cross-sectional view of an integrated circuit package system in a fourth embodiment of the present invention;

FIG. 7 is a cross-sectional view of an integrated circuit package system in a fifth embodiment of the present invention;

FIG. 8 is a cross-sectional view of an integrated circuit package system in a sixth embodiment of the present invention;

FIG. 9 is a cross-sectional view of an integrated circuit package system in a seventh embodiment of the present invention;

FIG. 10 is a cross-sectional view of an integrated circuit package system in an eighth embodiment of the present invention;

FIG. 11 is a cross-sectional view of the integrated circuit package system in a junction package forming phase;

FIG. 12 is a cross-sectional view of the integrated circuit package system in an integrated circuit mounting phase;

FIG. 13 is a cross-sectional view of the integrated circuit package system in a package forming phase;

FIG. 14 is a cross-sectional view of the integrated circuit package system in a base package forming phase;

FIG. 15 is a cross-sectional view of the integrated circuit package system in a junction package forming phase;

FIG. 16 is a cross-sectional view of the integrated circuit package system in a junction package mounting phase;

FIG. 17 is a cross-sectional view of the integrated circuit package system in a package subassembly forming phase;

FIG. 18 is a cross-sectional view of the integrated circuit package system in a junction package forming phase;

FIG. 19 is a cross-sectional view of the integrated circuit package system in a junction package mounting phase; and

FIG. 20 is a flow chart of an integrated circuit package system for manufacturing the integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs.

Where multiple embodiments are disclosed and described, having some features in common, for clarity and ease of illustration, description, and comprehension thereof, similar and like features one to another will ordinarily be described with like reference numerals. The embodiments may be numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the invention, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “on” as used herein means and refers to direct contact among elements. The term “processing” as used herein includes deposition of material, patterning, exposure, development, etching, cleaning, and/or removal of the material or trimming as required in forming a described structure. The term “system” as used herein means and refers to the method and to the apparatus of the present invention in accordance with the context in which the term is used.

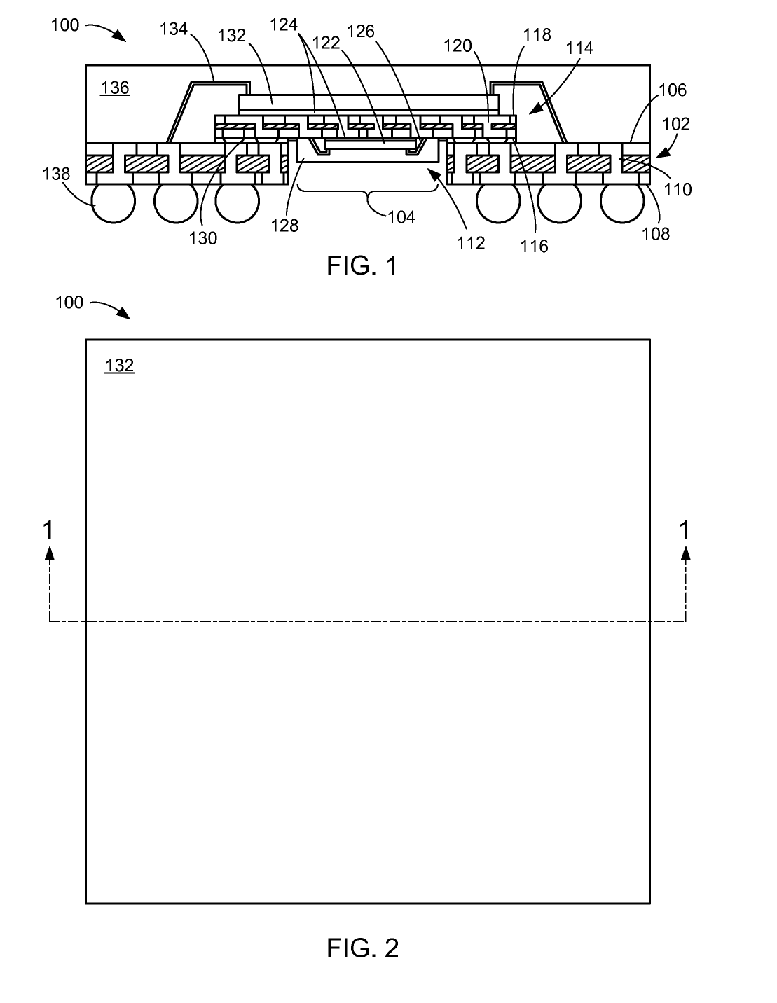

Referring now to FIG. 1, therein is shown a cross-sectional view of an integrated circuit package system 100 taken along line 1-1 of FIG. 2 in an embodiment of the present invention. The integrated circuit package system 100 such as a mother chip-scale package (mother CSP) preferably includes a base substrate 102 such as a mother substrate. The base substrate 102 includes a base substrate cavity 104, a base substrate first surface 106, a base substrate second surface 108, and a base substrate interconnect 110 to provide high flexibility for a mix of devices and packages.

A junction integrated circuit package 112 such as a daughter package includes a junction substrate 114 having a junction substrate first surface 116, a junction substrate second surface 118, and a junction substrate interconnect 120. A junction integrated circuit 122 can be mounted over the junction substrate first surface 116 with a die attach material 124 such as a non-conductive adhesive or a conductive adhesive.

A junction connector 126 can electrically connect the junction integrated circuit 122 and the junction substrate first surface 116. A junction package encapsulant 128 can be applied with a process such as a center gate molding over the junction integrated circuit 122, the junction connector 126, and a portion of the junction substrate first surface 116.

The junction integrated circuit package 112 can be mounted over the base substrate cavity 104 of the base substrate 102. For example, a package to package connection 130 such as a soldering connection can be formed between the junction substrate first surface 116 and the base substrate first surface 106. The package to package connection 130 can be formed adjacent the junction package encapsulant 128. The junction package encapsulant 128 can preferably be partially in the base substrate cavity 104 to meet the final product size.

A base integrated circuit 132 can be mounted over the base substrate first surface 106 with the die attach material 124 and electrically connected to the base substrate first surface 106 with a base connector 134. A base encapsulant 136 can be formed with a process such as a center gate molding over the base integrated circuit 132, the base connector 134, a portion of the junction substrate second surface 118, and a portion of the base substrate first surface 106. A package connector 138 such as solder bumps can preferably be formed over the base substrate second surface 108 for electrical connectivity to a next level system such as another package or a printed circuit board (PCB).

It has been discovered that the integrated circuit package system 100 with cavity substrate provides compatibility of components such as the junction integrated circuit package 112, the junction integrated circuit 122, and the base integrated circuit 132 for flexibility with multiple products and multi functional applications. Further, the present invention provides individual package electrical tests of the junction integrated circuit package 112, the junction integrated circuit 122, and the base integrated circuit 132 to minimize electrical failure rates. Yet further, the present invention provides optional stacking directions or orientations for components and packages to meet final product size requirements.

Referring now to FIG. 2 therein is shown a top plan view of the integrated circuit package system 100. The integrated circuit package system 100 preferably includes the base encapsulant 136. The base encapsulant 136 can preferably cover and protect the base integrated circuit 132 of FIG. 1, the base connector 134 of FIG. 1, a portion of the junction substrate second surface 118 of FIG. 1, and a portion of the base substrate first surface 106 of FIG. 1. For illustrative purposes, the integrated circuit package system 100 is shown in a shape of a square although it is understood that the integrated circuit package system 100 may be any shape or size.

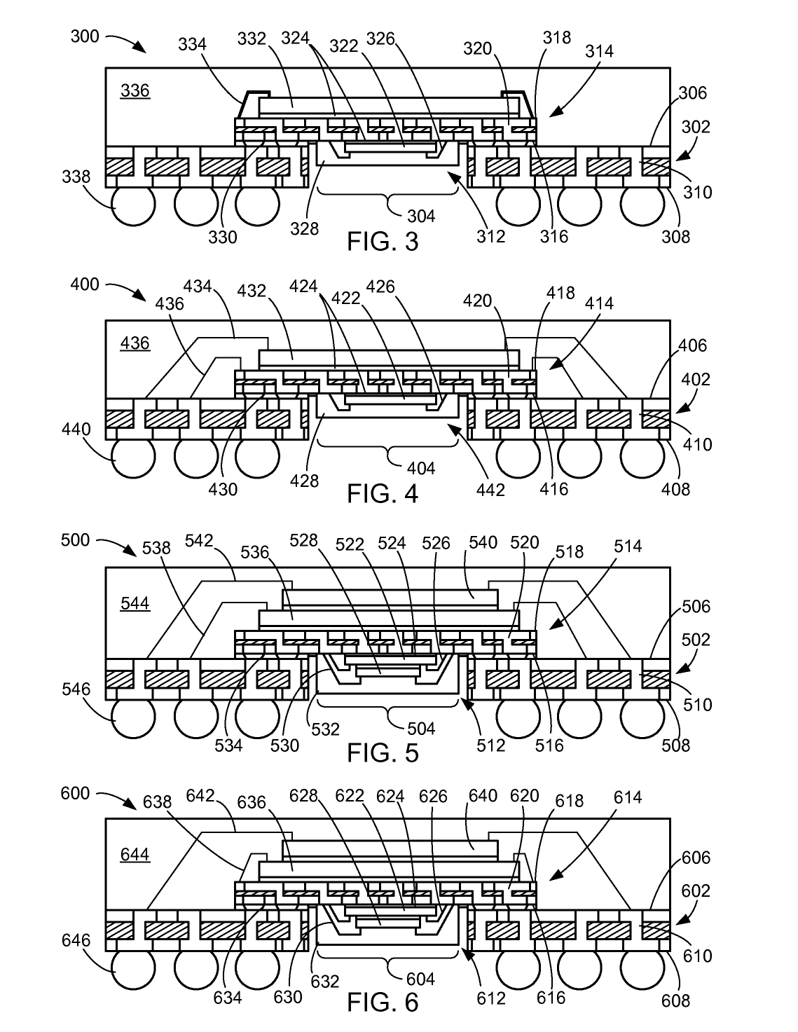

Referring now to FIG. 3, therein is shown a cross-sectional view of an integrated circuit package system 300 in a first embodiment of the present invention. The integrated circuit package system 300 such as a mother chip-scale package preferably includes a base substrate 302 such as a mother substrate. The base substrate 302 includes a base substrate cavity 304, a base substrate first surface 306, a base substrate second surface 308, and a base substrate interconnect 310 to provide high flexibility for a mix of devices and packages.

A junction integrated circuit package 312 such as a daughter package includes a junction substrate 314 having a junction substrate first surface 316, a junction substrate second surface 318, and a junction substrate interconnect 320. A junction integrated circuit 322 can be mounted over the junction substrate first surface 316 with a die attach material 324 such as a non-conductive adhesive or a conductive adhesive.

A junction connector 326 can electrically connect the junction integrated circuit 322 and the junction substrate first surface 316. A junction package encapsulant 328 can be applied with a process such as a center gate molding over the junction integrated circuit 322, the junction connector 326, and a portion of the junction substrate first surface 316.

The junction integrated circuit package 312 can be mounted over the base substrate cavity 304 of the base substrate 302. For example, a package to package connection 330 such as a soldering connection can be formed between the junction substrate first surface 316 and the base substrate first surface 306. The package to package connection 330 can be formed adjacent the junction package encapsulant 328. The junction package encapsulant 328 can preferably be partially in the base substrate cavity 304 to meet the final product size.

A base integrated circuit 332 can be mounted over the base substrate first surface 306 with the die attach material 324 and electrically connected to the base substrate first surface 306 with a base connector 334. A base encapsulant 336 can be formed with a process such as a center gate molding over the base integrated circuit 332, the base connector 334, a portion of the junction substrate second surface 318, and a portion of the base substrate first surface 306. A package connector 338 such as solder bumps can preferably be formed over the base substrate second surface 308 for electrical connectivity to a next level system such as another package or a printed circuit board.

Referring now to FIG. 4, therein is shown a cross-sectional view of an integrated circuit package system 400 in a second embodiment of the present invention. The integrated circuit package system 400 such as a mother chip-scale package preferably includes a base substrate 402 such as a mother substrate. The base substrate 402 includes a base substrate cavity 404, a base substrate first surface 406, a base substrate second surface 408, and a base substrate interconnect 410 to provide high flexibility for a mix of devices and packages.

A junction integrated circuit package 412 such as a daughter package includes a junction substrate 414 having a junction substrate first surface 416, a junction substrate second surface 418, and a junction substrate interconnect 420. A junction integrated circuit 422 can be mounted over the junction substrate first surface 416 with a die attach material 424 such as a non-conductive adhesive or a conductive adhesive.

A junction connector 426 can electrically connect the junction integrated circuit 422 and the junction substrate first surface 416. A junction package encapsulant 428 can be applied with a process such as a center gate molding over the junction integrated circuit 422, the junction connector 426, and a portion of the junction substrate first surface 416.

The junction integrated circuit package 412 can be mounted over the base substrate cavity 404 of the base substrate 402. For example, a package to package connection 430 such as a non-conductive adhesive can be formed between the junction substrate first surface 416 and the base substrate first surface 406. The package to package connection 430 can be formed adjacent the junction package encapsulant 428. The junction package encapsulant 428 can preferably be partially in the base substrate cavity 404 to meet the final product size.

A base integrated circuit 432 can be mounted over the base substrate first surface 406 with the die attach material 424 and electrically connected to the base substrate first surface 406 with a base first connector 434. A base second connector 436 can connect the junction substrate second surface 418 and the base substrate first surface 406. A base encapsulant 438 can be formed with a process such as a center gate molding over the base integrated circuit 432, the base first connector 434, a portion of the junction substrate second surface 418, and a portion of the base substrate first surface 406. A package connector 440 such as solder bumps can preferably be formed over the base substrate second surface 408 for electrical connectivity to a next level system such as another package or a printed circuit board.

Referring now to FIG. 5, therein is shown a cross-sectional view of an integrated circuit package system 500 in a third embodiment of the present invention. The integrated circuit package system 500 such as a mother chip-scale package preferably includes a base substrate 502 such as a mother substrate. The base substrate 502 includes a base substrate cavity 504, a base substrate first surface 506, a base substrate second surface 508, and a base substrate interconnect 510 to provide high flexibility for a mix of devices and packages.

A junction integrated circuit package 512 such as a daughter package includes a junction substrate 514 having a junction substrate first surface 516, a junction substrate second surface 518, and a junction substrate interconnect 520. A junction first integrated circuit 522 can be mounted over the junction substrate first surface 516 with a die attach material 524 such as a non-conductive adhesive or a conductive adhesive.

A junction first connector 526 can electrically connect the junction first integrated circuit 522 and the junction substrate first surface 516. A junction second integrated circuit 528 can be mounted over the junction first integrated circuit 522 with the die attach material 524. A junction second connector 530 can electrically connect the junction second integrated circuit 528 and the junction substrate first surface 516.

A junction package encapsulant 532 can be applied with a process such as a center gate molding over the junction first integrated circuit 522, the junction first connector 526, the junction second integrated circuit 528, the junction second connector 530, a portion of the junction substrate second surface 518, and a portion of the base substrate first surface 506. The junction integrated circuit package 512 can be mounted over the base substrate cavity 504 of the base substrate 502.

For example, a package to package connection 534 such as a soldering connection can be formed between the junction substrate first surface 516 and the base substrate first surface 506. The package to package connection 534 can be formed adjacent the junction package encapsulant 532. The junction package encapsulant 532 can preferably be partially in the base substrate cavity 504 to meet the final product size.

A base first integrated circuit 536 can be mounted over the base substrate first surface 506 with the die attach material 524 and electrically connected to the base substrate first surface 506 with a base first connector 538. A base second integrated circuit 540 can be mounted over the base first integrated circuit 536 with the die attach material 524 and electrically connected to the base substrate first surface 506 with a base second connector 542.

A base encapsulant 544 can be formed with a process such as a center gate molding over the base first integrated circuit 536, the base first connector 538, and a portion of the base substrate first surface 506. A package connector 546 such as solder bumps can preferably be formed over the base substrate second surface 508 for electrical connectivity to a next level system such as another package or a printed circuit board.

Referring now to FIG. 6, therein is shown a cross-sectional view of an integrated circuit package system 600 in a fourth embodiment of the present invention. Similar to the integrated circuit package system 500, the integrated circuit package system 600 such as a mother chip-scale package preferably includes a base substrate 602 such as a mother substrate. The base substrate 602 includes a base substrate cavity 604, a base substrate first surface 606, a base substrate second surface 608, and a base substrate interconnect 610 to provide high flexibility for a mix of devices and packages.

A junction integrated circuit package 612 such as a daughter package includes a junction substrate 614 having a junction substrate first surface 616, a junction substrate second surface 618, and a junction substrate interconnect 620. A junction first integrated circuit 622 can be mounted over the junction substrate first surface 616 with a die attach material 624 such as a non-conductive adhesive or a conductive adhesive.

A junction first connector 626 can electrically connect the junction first integrated circuit 622 and the junction substrate first surface 616. A junction second integrated circuit 628 can be mounted over the junction first integrated circuit 622 with the die attach material 624. A junction second connector 630 can electrically connect the junction second integrated circuit 628 and the junction substrate first surface 616.

A junction package encapsulant 632 can be applied with a process such as a center gate molding over the junction first integrated circuit 622, the junction first connector 626, the junction second integrated circuit 628, the junction second connector 630, a portion of the junction substrate second surface 618, and a portion of the base substrate first surface 606. The junction integrated circuit package 612 can be mounted over the base substrate cavity 604 of the base substrate 602.

For example, a package to package connection 634 such as a soldering connection can be formed between the junction substrate first surface 616 and the base substrate first surface 606. The package to package connection 634 can be formed adjacent the junction package encapsulant 632. The junction package encapsulant 632 can preferably be partially in the base substrate cavity 604 to meet the final product size.

A base first integrated circuit 636 can be mounted over the base substrate first surface 606 with the die attach material 624 and electrically connected to the junction substrate second surface 618 with a base first connector 638. A base second integrated circuit 640 can be mounted over the base first integrated circuit 636 with the die attach material 624 and electrically connected to the base substrate first surface 606 with a base second connector 642.

A base encapsulant 644 can be formed with a process such as a center gate molding over the base first integrated circuit 636, the base first connector 638, and a portion of the base substrate first surface 606. A package connector 646 such as solder bumps can preferably be formed over the base substrate second surface 608 for electrical connectivity to a next level system such as another package or a printed circuit board.

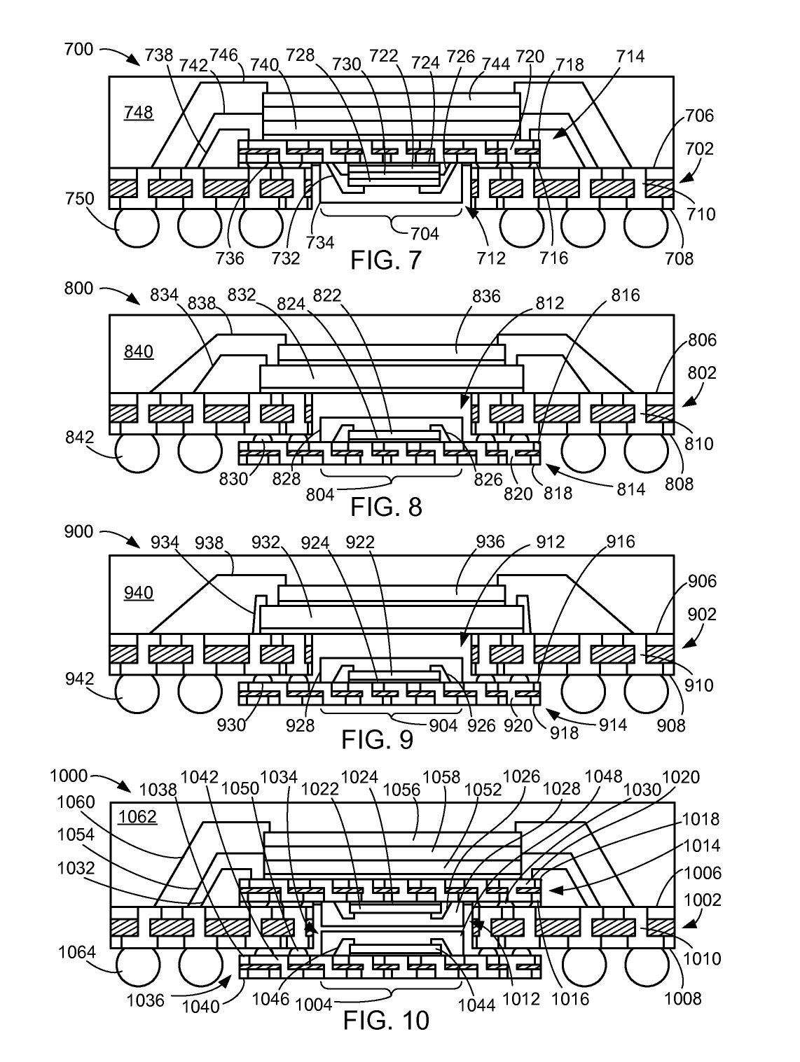

Referring now to FIG. 7, therein is shown a cross-sectional view of an integrated circuit package system 700 in a fifth embodiment of the present invention. The integrated circuit package system 700 such as a mother chip-scale package preferably includes a base substrate 702 such as a mother substrate. The base substrate 702 includes a base substrate cavity 704, a base substrate first surface 706, a base substrate second surface 708, and a base substrate interconnect 710 to provide high flexibility for a mix of devices and packages.

A junction integrated circuit package 712 such as a daughter package includes a junction substrate 714 having a junction substrate first surface 716, a junction substrate second surface 718, and a junction substrate interconnect 720. A junction first integrated circuit 722 can be mounted over the junction substrate first surface 716 with a die attach material 724 such as a non-conductive adhesive or a conductive adhesive. A junction first connector 726 can electrically connect the junction first integrated circuit 722 and the junction substrate first surface 716.

A junction second integrated circuit 728 can be mounted over the junction first integrated circuit 722 with a mounting layer 730 such as a spacer, an adhesive, a resin, or any combination thereof. A junction second connector 732 can electrically connect the junction second integrated circuit 728 and the junction substrate first surface 716.

A junction package encapsulant 734 can be applied with a process such as a center gate molding over the junction first integrated circuit 722, the junction first connector 726, the junction second integrated circuit 728, the junction second connector 732, a portion of the junction substrate second surface 718, and a portion of the base substrate first surface 706. The junction integrated circuit package 712 can be mounted over the base substrate cavity 704 of the base substrate 702.

For example, a package to package connection 736 such as a non-conductive adhesive can be formed between the junction substrate first surface 716 and the base substrate first surface 706. The package to package connection 736 can be formed adjacent the junction package encapsulant 734. The junction package encapsulant 734 can preferably be partially in the base substrate cavity 704 to meet the final product size. A junction to base connector 738 can electrically connect the junction substrate second surface 718 to the base substrate first surface 706.

A base first integrated circuit 740 can be mounted over the base substrate first surface 706 with the die attach material 724 and electrically connected to the junction substrate second surface 718 with a base first connector 742. A base second integrated circuit 744 can be mounted over the base first integrated circuit 740 with the mounting layer 730 and electrically connected to the base substrate first surface 706 with a base second connector 746.

A base encapsulant 748 can be formed with a process such as a center gate molding over the base first integrated circuit 740, the base first connector 742, and a portion of the base substrate first surface 706. A package connector 750 such as solder bumps can preferably be formed over the base substrate second surface 708 for electrical connectivity to a next level system such as another package or a printed circuit board.

Referring now to FIG. 8, therein is shown a cross-sectional view of an integrated circuit package system 800 in a sixth embodiment of the present invention. The integrated circuit package system 800 such as a mother chip-scale package preferably includes a base substrate 802 such as a mother substrate. The base substrate 802 includes a base substrate cavity 804, a base substrate first surface 806, a base substrate second surface 808, and a base substrate interconnect 810 to provide high flexibility for a mix of devices and packages.

A junction integrated circuit package 812 such as a daughter package includes a junction substrate 814 having a junction substrate first surface 816, a junction substrate second surface 818, and a junction substrate interconnect 820. A junction integrated circuit 822 can be mounted over the junction substrate first surface 816 with a die attach material 824 such as a non-conductive adhesive or a conductive adhesive.

A junction connector 826 can electrically connect the junction integrated circuit 822 and the junction substrate first surface 816. A junction package encapsulant 828 can be applied with a process such as a center gate molding over the junction integrated circuit 822, the junction connector 826, and a portion of the junction substrate first surface 816.

The junction integrated circuit package 812 can be mounted under the base substrate cavity 804 of the base substrate 802. For example, a package to package connection 830 such as a soldering application can be formed between the junction substrate first surface 816 and the base substrate second surface 808. The package to package connection 830 can be formed adjacent the junction package encapsulant 828. The junction package encapsulant 828 can preferably be partially in the base substrate cavity 804 to meet the final product size.

A base first integrated circuit 832 can be mounted over the base substrate first surface 806 with the die attach material 824 and electrically connected to the base substrate first surface 806 with a base first connector 834. A base second integrated circuit 836 can be mounted over the base first integrated circuit 832 with the die attach material 824 and electrically connected to the base substrate first surface 806 with a base second connector 838.

A base encapsulant 840 can be formed with a process such as a center gate molding over the base first integrated circuit 832, the base first connector 834, and a portion of the base substrate first surface 806. A package connector 842 such as solder bumps can preferably be formed over the base substrate second surface 808 for electrical connectivity to a next level system such as another package or a printed circuit board.

Referring now to FIG. 9, therein is shown a cross-sectional view of an integrated circuit package system 900 in a seventh embodiment of the present invention. Similar to the integrated circuit package system 800, the integrated circuit package system 900 such as a mother chip-scale package preferably includes a base substrate 902 such as a mother substrate. The base substrate 902 includes a base substrate cavity 904, a base substrate first surface 906, a base substrate second surface 908, and a base substrate interconnect 910 to provide high flexibility for a mix of devices and packages.

A junction integrated circuit package 912 such as a daughter package includes a junction substrate 914 having a junction substrate first surface 916, a junction substrate second surface 918, and a junction substrate interconnect 920. A junction integrated circuit 922 can be mounted over the junction substrate first surface 916 with a die attach material 924 such as a non-conductive adhesive or a conductive adhesive.

A junction connector 926 can electrically connect the junction integrated circuit 922 and the junction substrate first surface 916. A junction package encapsulant 928 can be applied with a process such as a center gate molding over the junction integrated circuit 922, the junction connector 926, and a portion of the junction substrate first surface 916.

The junction integrated circuit package 912 can be mounted under the base substrate cavity 904 of the base substrate 902. For example, a package to package connection 930 such as a soldering application can be formed between the junction substrate first surface 916 and the base substrate second surface 908. The package to package connection 930 can be formed adjacent the junction package encapsulant 928. The junction package encapsulant 928 can preferably be partially in the base substrate cavity 904 to meet the final product size.

A base first integrated circuit 932 can be mounted over the base substrate first surface 906 with the die attach material 924 and electrically connected to the base substrate first surface 906 with a base first connector 934. A base second integrated circuit 936 can be mounted over the base first integrated circuit 932 with the die attach material 924 and electrically connected to the base substrate first surface 906 with a base second connector 938.

A base encapsulant 940 can be formed with a process such as a center gate molding over the base first integrated circuit 932, the base first connector 934, and a portion of the base substrate first surface 906. A package connector 942 such as solder bumps can preferably be formed over the base substrate second surface 908 for electrical connectivity to a next level system such as another package or a printed circuit board.

Referring now to FIG. 10, therein is shown a cross-sectional view of an integrated circuit package system 1000 in an eighth embodiment of the present invention. Similar to the integrated circuit package system 700, the integrated circuit package system 1000 such as a mother chip-scale package preferably includes a base substrate 1002 such as a mother substrate. The base substrate 1002 includes a base substrate cavity 1004, a base substrate first surface 1006, a base substrate second surface 1008, and a base substrate interconnect 1010 to provide high flexibility for a mix of devices and packages.

A junction first package 1012 such as a daughter package includes a junction first substrate 1014 having a junction first substrate first surface 1016, a junction first substrate second surface 1018, and a junction first substrate interconnect 1020. A junction first integrated circuit 1022 can be mounted over the junction first substrate first surface 1016 with a die attach material 1024 such as a non-conductive adhesive or a conductive adhesive. A junction first connector 1026 can electrically connect the junction first integrated circuit 1022 and the junction first substrate first surface 1016.

A junction first package encapsulant 1028 can be applied with a process such as a center gate molding over the junction first integrated circuit 1022, the junction first connector 1026, and a portion of the junction first substrate first surface 1016. The junction first package 1012 can be mounted over the base substrate cavity 1004 of the base substrate 1002.

For example, a package to package first connection 1030 such as a non-conductive adhesive can be formed between the junction first substrate first surface 1016 and the base substrate first surface 1006. The package to package first connection 1030 can be formed adjacent the junction first package encapsulant 1028. The junction first package encapsulant 1028 can preferably be partially in the base substrate cavity 1004 to meet the final product size. A junction to base connector 1032 can electrically connect the junction first substrate second surface 1018 to the base substrate first surface 1006.

A junction second package 1034 such as a daughter package includes a junction second substrate 1036 having a junction second substrate first surface 1038, a junction second substrate second surface 1040, and a junction second substrate interconnect 1042. A junction second integrated circuit 1044 can be mounted over the junction second substrate first surface 1038 with the die attach material 1024. A junction second connector 1046 can electrically connect the junction second integrated circuit 1044 and the junction second substrate first surface 1038.

A junction second package encapsulant 1048 can be applied with a process such as a center gate molding over the junction second integrated circuit 1044, the junction second connector 1046, and a portion of the junction second substrate first surface 1038. The junction second package 1034 can be mounted under the base substrate cavity 1004 of the base substrate 1002.

For example, a package to package second connection 1050 such as a soldering application can be formed between the junction second substrate first surface 1038 and the base substrate second surface 1008. The package to package second connection 1050 can be formed adjacent the junction second package encapsulant 1048. The junction second package encapsulant 1048 can preferably be partially in the base substrate cavity 1004 to meet the final product size. The package to package second connection 1050 can electrically connect the junction second substrate first surface 1038 to the base substrate second surface 1008.

A base first integrated circuit 1052 can be mounted over the base substrate first surface 1006 with the die attach material 1024 and electrically connected to the junction first substrate second surface 1018 with a base first connector 1054. A base second integrated circuit 1056 can be mounted over the base first integrated circuit 1052 with a mounting layer 1058 such as a spacer, an adhesive, a resin, or any combination thereof and electrically connected to the base substrate first surface 1006 with a base second connector 1060.

A base encapsulant 1062 can be formed with a process such as a center gate molding over the base first integrated circuit 1052, the base first connector 1054, the base second integrated circuit 1056, the base second connector 1060, the junction to base connector 1032, a portion of the junction first substrate second surface 1018, and a portion of the base substrate first surface 1006. A package connector 1064 such as solder bumps can preferably be formed over the base substrate second surface 1008 for electrical connectivity to a next level system such as another package or a printed circuit board.

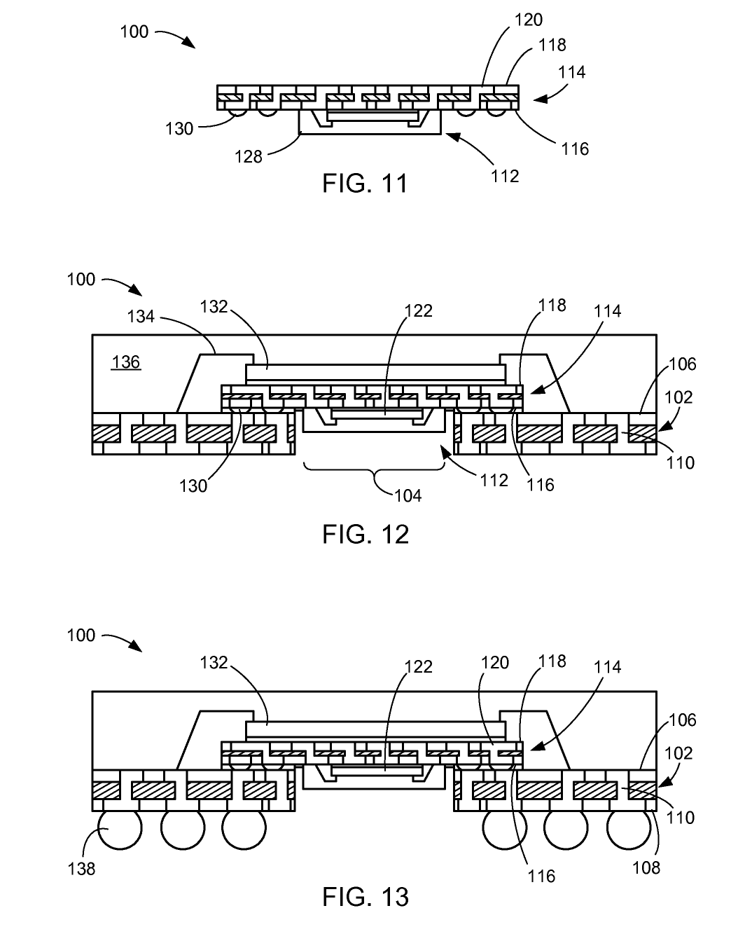

Referring now to FIG. 11, therein is shown a cross-sectional view of the integrated circuit package system 100 in a junction package forming phase. The junction integrated circuit package 112 includes the junction substrate 114 having the junction substrate first surface 116, the junction substrate second surface 118, and the junction substrate interconnect 120. The package to package connection 130 can be formed over the junction substrate first surface 116. The package to package connection 130 can further be formed adjacent the junction package encapsulant 128.

Referring now to FIG. 12, therein is shown a cross-sectional view of the integrated circuit package system 100 in an integrated circuit mounting phase. The junction substrate first surface 116 of the junction integrated circuit package 112 can be mounted over the base substrate first surface 106. The package to package connection 130 can provide physical connectivity. The junction integrated circuit 122 of the junction integrated circuit package 112 can be partially in the base substrate cavity 104 of the base substrate 102 to meet the final product size.

The base integrated circuit 132 can be mounted over the junction substrate second surface 118 with the die attach material 124. The base encapsulant 136 can be formed over the base integrated circuit 132, the base connector 134, a portion of the junction substrate second surface 118, and a portion of the base substrate first surface 106.

Referring now to FIG. 13, therein is shown a cross-sectional view of the integrated circuit package system 100 in a package forming phase. The integrated circuit package system 100 includes the package connector 138 preferably formed under the base substrate second surface 108 for electrical connectivity to a next level system such as another package or a printed circuit board.

The package connector 138 can also provides electrical connectivity to the base substrate second surface 108, the base substrate interconnect 110, and the base substrate first surface 106. Electrical connectivity can also include the package to package connection 130, the junction substrate first surface 116, the junction substrate interconnect 120, and the junction substrate second surface 118. The base substrate 102 and the junction substrate 114 can provide electrical connectivity to the junction integrated circuit 122 and the base integrated circuit 132.

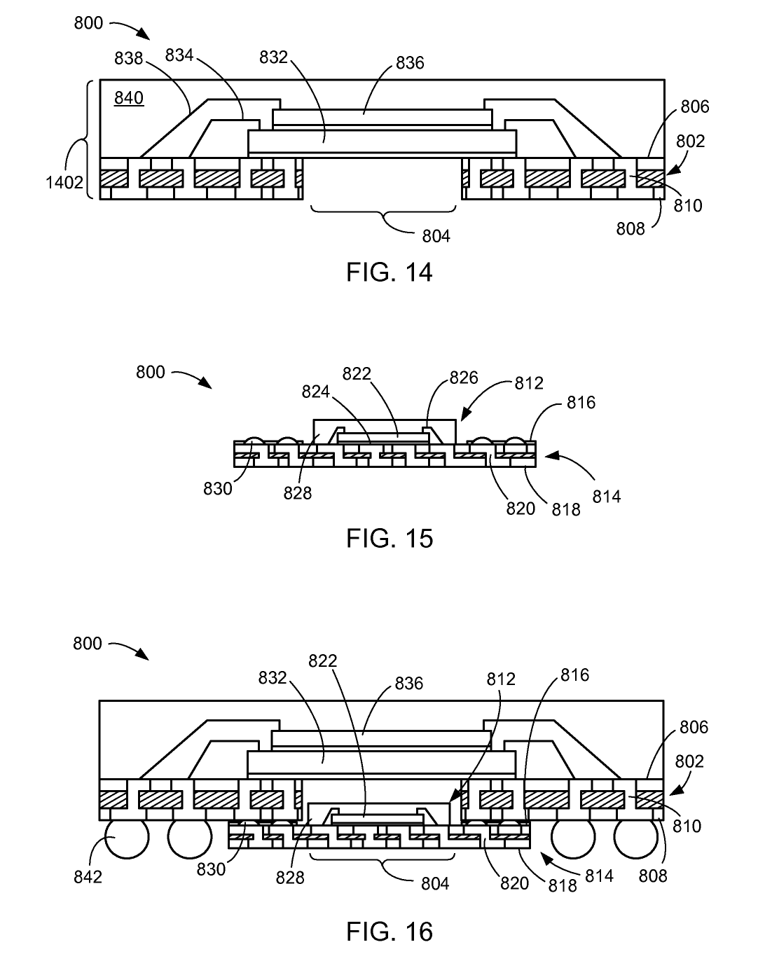

Referring now to FIG. 14, therein is shown a cross-sectional view of the integrated circuit package system 800 in a base package forming phase. The integrated circuit package system 800 includes a base integrated circuit package 1402 having the base substrate 802 with the base substrate cavity 804, the base substrate first surface 806, the base substrate second surface 808, and the base substrate interconnect 810.

The base integrated circuit package 1402 also includes the base first integrated circuit 832 over the base substrate first surface 806 and the base second integrated circuit 836 over the base first integrated circuit 832. The base first connector 834 connects the base first integrated circuit 832 and the base substrate first surface 806. The base second connector 838 connects the base substrate second surface 808 and the base substrate first surface 806. The base encapsulant 840 covers and protects the base first integrated circuit 832, the base second integrated circuit 836, the base first connector 834, the base second connector 838, and a portion of the base substrate first surface 806.

Referring now to FIG. 15, therein is shown a cross-sectional view of the integrated circuit package system 800 in a junction package forming phase. The integrated circuit package system 800 includes the junction integrated circuit package 812 having the junction substrate 814 with the junction substrate first surface 816, the junction substrate second surface 818, and the junction substrate interconnect 820.

The junction integrated circuit 822 can be mounted over the junction substrate first surface 816 with the die attach material 824. The junction connector 826 can electrically connect the junction integrated circuit 822 and the junction substrate first surface 816. The junction package encapsulant 828 can be applied over the junction integrated circuit 822, the junction connector 826, and a portion of the junction substrate first surface 816. The package to package connection 830 can be formed over the junction substrate first surface 816.

Referring now to FIG. 16, therein is shown a cross-sectional view of the integrated circuit package system 800 in a junction package mounting phase. The junction integrated circuit package 812 can be mounted under the base substrate 802. The package to package connection 830 over the junction substrate first surface 816 can preferably be attached to the base substrate second surface 808 with the junction package encapsulant 828 partially in the base substrate cavity 804. The package to package connection 830 can provide physical connectivity. The package connector 842 can preferably be formed under the base substrate second surface 808 for electrical connectivity to a next level system such as another package or a printed circuit board.

The package connector 842 can also provides electrical connectivity to the base substrate second surface 808, the base substrate interconnect 810, and the base substrate first surface 806. Electrical connectivity can also include the package to package connection 830, the junction substrate first surface 816, the junction substrate interconnect 820, and the junction substrate second surface 818. The base substrate 802 and the junction substrate 814 can provide electrical connectivity to the junction integrated circuit 822, the base first integrated circuit 832, and the base second integrated circuit 836.

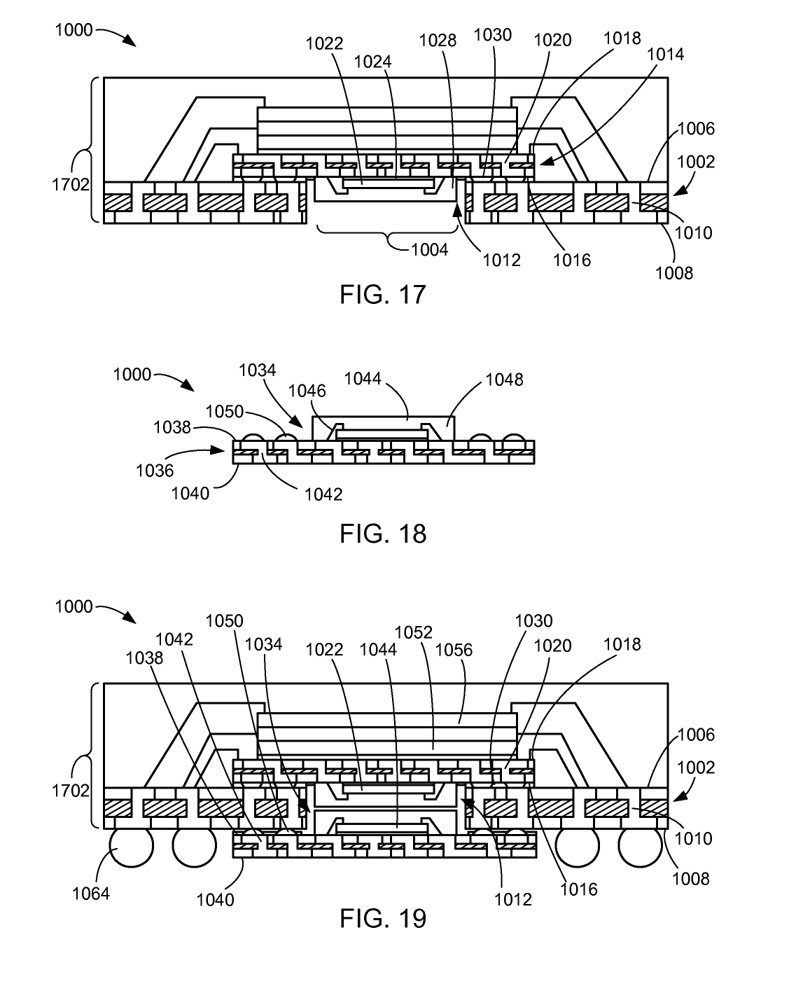

Referring now to FIG. 17, therein is shown a cross-sectional view of the integrated circuit package system 1000 in a package subassembly forming phase. The integrated circuit package system 1000 includes a base subassembly 1702 having the base substrate 1002 with the base substrate cavity 1004, the base substrate first surface 1006, the base substrate second surface 1008, and the base substrate interconnect 1010.

The base subassembly 1702 also includes the junction first package 1012 having the junction first substrate first surface 1016, the junction first substrate second surface 1018, and the junction first substrate interconnect 1020. The junction first integrated circuit 1022 can be mounted over the junction first substrate first surface 1016 with the die attach material 1024.

The junction first package encapsulant 1028 can be applied over the junction first integrated circuit 1022, the junction first connector 1026, and a portion of the junction first substrate first surface 1016. The junction first package 1012 can be mounted over the base substrate cavity 1004 of the base substrate 1002.

The package to package first connection 1030 can be formed between the junction first substrate first surface 1016 and the base substrate first surface 1006. The junction first package encapsulant 1028 can preferably be partially in the base substrate cavity 1004.

Referring now to FIG. 18, therein is shown a cross-sectional view of the integrated circuit package system 1000 in a junction package forming phase. The integrated circuit package system 1000 includes the junction second package 1034 having the junction second substrate first surface 1038, the junction second substrate second surface 1040, and the junction second substrate interconnect 1042. The junction second integrated circuit 1044 can be mounted over the junction second substrate first surface 1038 with the die attach material 1024. The junction second connector 1046 can electrically connect the junction second integrated circuit 1044 and the junction second substrate first surface 1038.

The junction second package encapsulant 1048 can be applied over the junction second integrated circuit 1044, the junction second connector 1046, and a portion of the junction second substrate first surface 1038. The package to package second connection 1050 can be formed over the junction second substrate first surface 1038 and adjacent the junction second package encapsulant 1048.

Referring now to FIG. 19, therein is shown a cross-sectional view of the integrated circuit package system 1000 in a junction package mounting phase. The junction second package 1034 can preferably be mounted under the base subassembly 1702. The package to package second connection 1050 can be attached to the junction second substrate first surface 1038 and the base substrate first surface 1006. The package connector 1064 can preferably be formed under the base substrate second surface 1008 for electrical connectivity to a next level system such as another package or a printed circuit board.

The package connector 1064 can also provides electrical connectivity to the base substrate second surface 1008, the base substrate interconnect 1010, and the base substrate first surface 1006. Electrical connectivity can also include the package to package first connection 1030, the junction first substrate first surface 1016, the junction first substrate interconnect 1020, and the junction first substrate second surface 1018. Further electrical connectivity includes the package to package second connection 1050, the junction second substrate first surface 1038, the junction second substrate interconnect 1042, and the junction second substrate second surface 1040.

The base substrate 1002, the junction first substrate 1014, and the junction second substrate 1036 can provide electrical connectivity to the junction first integrated circuit 1022, the junction second integrated circuit 1044, the base first integrated circuit 1052, and the base second integrated circuit 1056.

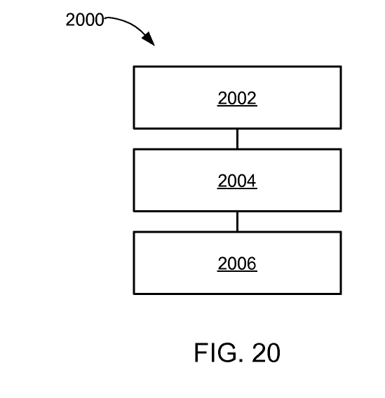

Referring now to FIG. 20, therein is shown a flow chart of an integrated circuit package system 2000 for manufacturing the integrated circuit package system 100 in an embodiment of the present invention. The system 2000 includes providing a base substrate having a base substrate cavity in a block 2002; attaching a junction integrated circuit package over the base substrate with a portion of the junction integrated circuit package in the base substrate cavity in a block 2004; and attaching a base integrated circuit over the junction integrated circuit package and the base substrate in a block 2006.

In greater detail, a system to provide the method and apparatus of the integrated circuit package system 100, in an embodiment of the present invention, is performed as follows:
1. Forming a base substrate having a base substrate cavity, a base substrate first surface, and a base substrate second surface.
2. Mounting a junction integrated circuit package having a junction integrated circuit over the base substrate with a portion of the junction integrated circuit in the base substrate cavity.
3. Mounting a base integrated circuit over the junction integrated circuit package and the base substrate first surface.

Thus, it has been discovered that the integrated circuit package system method and apparatus of the present invention furnish important and heretofore unknown and unavailable solutions, capabilities, and functional aspects. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit package system comprising:
providing a base substrate having a base substrate cavity;
attaching a junction integrated circuit package over the base substrate with a portion of the junction integrated circuit package in the base substrate cavity; and
attaching a base integrated circuit over the junction integrated circuit package and the base substrate.

2. The system as claimed in claim 1 wherein attaching the junction integrated circuit package includes attaching a package to package connection to a junction substrate of the junction integrated circuit package and the base substrate.

3. The system as claimed in claim 1 further comprising attaching a base connector to the base integrated circuit and the base substrate first surface.

4. The system as claimed in claim 1 further comprising attaching a base connector to the base integrated circuit and the junction substrate second surface.

5. The system as claimed in claim 1 further comprising attaching a package connector to the junction substrate second surface and the base substrate first surface.

6. An integrated circuit package system comprising:
forming a base substrate having a base substrate cavity, a base substrate first surface, and a base substrate second surface;
mounting a junction integrated circuit package having a junction integrated circuit over the base substrate with a portion of the junction integrated circuit in the base substrate cavity; and
mounting a base integrated circuit over the junction integrated circuit package and the base substrate first surface.

7. The system as claimed in claim 6 wherein mounting the junction integrated circuit package includes mounting the junction integrated circuit package over a base substrate first surface.

8. The system as claimed in claim 6 wherein mounting the junction integrated circuit package includes mounting the junction integrated circuit package over a base substrate second surface.

9. The system as claimed in claim 6 wherein mounting the base integrated circuit includes mounting the base integrated circuit over a junction substrate second surface.

10. The system as claimed in claim 6 wherein mounting the base integrated circuit includes mounting the base integrated circuit over a base substrate first surface.

11. An integrated circuit package system comprising:
a base substrate having a base substrate cavity;
a junction integrated circuit package over the base substrate with a portion of the junction integrated circuit package in the base substrate cavity; and
a base integrated circuit over the junction integrated circuit package and the base substrate.

12. The system as claimed in claim 11 wherein the junction integrated circuit package includes a package to package connection to a junction substrate of the junction integrated circuit package and the base substrate.

13. The system as claimed in claim 11 further comprising a base connector attached to the base integrated circuit and the base substrate first surface.

14. The system as claimed in claim 11 further comprising a base connector attached to the base integrated circuit and the junction substrate second surface.

15. The system as claimed in claim 11 further comprising a package connector attached to the junction substrate second surface and the base substrate first surface.

16. The system as claimed in claim 11 wherein:
the base substrate has the base substrate cavity, a base substrate first surface, and a base substrate second surface;
the junction integrated circuit package has a junction integrated circuit over the base substrate with a portion of the junction integrated circuit in the base substrate cavity; and
the base integrated circuit is over the junction integrated circuit package and the base substrate first surface of the base substrate.

17. The system as claimed in claim 16 wherein the junction integrated circuit package includes the junction integrated circuit package over a base substrate first surface.

18. The system as claimed in claim 16 wherein the junction integrated circuit package includes the junction integrated circuit package over a base substrate second surface.

19. The system as claimed in claim 16 wherein the base integrated circuit includes the base integrated circuit over a junction substrate second surface.

20. The system as claimed in claim 16 wherein the base integrated circuit includes the base integrated circuit over a base substrate first surface.
